(19) United States
(12) Patent Application Publication
(10) Pub. No.: US 2025/0301804 A1
(43) Pub. Date: Sep. 25, 2025

(54) PHOTOVOLTAIC TILE

(71) Applicant: SHENZHEN HELLO TECH ENERGY CO., LTD, Shenzhen, Guangdong (CN)

(72) Inventors: Fengwen CHEN, Shenzhen (CN); Zhongwei SUN, Shenzhen (CN); Xingchen JIANG, Shenzhen (CN); Yanjun ZHU, Shenzhen (CN)

(21) Appl. No.: 19/230,146

(22) Filed: Jun. 6, 2025

Related U.S. Application Data
(63) Continuation of application No. PCT/CN2025/070556, filed on Jan. 3, 2025.

(30) Foreign Application Priority Data
Feb. 26, 2024 (CN) 202420353914.5
Feb. 27, 2024 (CN) 202420372848.6

(51) Int. Cl. H10F 19/90; H02S 20/25

(52) U.S. Cl. CPC H10F 19/904; H02S 20/25

(57) ABSTRACT

Provided is a photovoltaic tile (100). The photovoltaic tile (100) includes: a first plate body (110) and a second plate body (120); a solar module (130) disposed between the first plate body (110) and the second plate body (120). The solar module (130) includes a plurality of solar cells (131). The plurality of solar cells (131) includes at least a first solar cell (131) and a second solar cell (131) adjacent to the first solar cell (131). The first solar cell (131) has a portion overlapping with and being electrically connected to a portion of the second solar cell (131). At least one of the first plate body (110) and the second plate body (120) is configured as a rigid curved panel. The rigid curved panel includes a plurality of curved portions (140) that are sequentially connected to each other.

### CROSS-REFERENCE TO RELATED APPLICATION

This application is a continuation of the PCT application with International Application No. PCT/CN2025/070556, filed on Jan. 3, 2025, which claims priority to and benefits of the patent application No. 202420372848.6, filed with the China National Intellectual Property Administration on Feb. 27, 2024, and the patent application No. 202420353914.5, filed with the China National Intellectual Property Administration on Feb. 26, 2024, the entire contents of which are incorporated herein by reference.

### FIELD

The present disclosure relates to the field of photovoltaic equipment technologies, and more particularly, to a photovoltaic tile.

### BACKGROUND

With continuous improvement of photovoltaic power generation technology and emergence of new products, aesthetics of roof photovoltaic modules in the related art are far from meeting people's design needs for photovoltaic building projects. In addition, a battery string layer of a curved photovoltaic tile generally includes welding ribbons, which affects aesthetics of photovoltaic products. Moreover, during lamination, a solar cell is prone to cracking.

### SUMMARY

The present disclosure aims to solve at least one of the technical problems in the related art or in the prior art.

To this end, in a first aspect, an embodiment of the present disclosure provides a photovoltaic tile.

In view of this, according to a first aspect of an embodiment of the present disclosure, a photovoltaic tile is provided. The photovoltaic tile includes: a first plate body and a second plate body; and a solar module disposed between the first plate body and the second plate body, the solar module including a plurality of solar cells, the plurality of solar cells including at least a first solar cell and a second solar cell adjacent to the first solar cell, and the first solar cell having a portion overlapping with and being electrically connected to a portion of the second solar cell. At least one of the first plate body and the second plate body is configured as a rigid curved panel, the rigid curved panel including a plurality of curved portions that are sequentially connected to each other.

The photovoltaic tile according to the embodiment of the present disclosure includes the first plate body, the second plate body, and the solar module. In particular, the solar module is disposed between the first plate body and the second plate body. In another exemplary embodiment of the present disclosure, the first plate body is located at a light-receiving side of the solar module. The second plate body is located at a rear side of the solar module. The first plate body is capable of transmitting light, in such a manner that the solar module can convert light energy into electrical energy under illumination conditions.

The solar module includes the plurality of solar cells. The plurality of solar cells includes at least the first solar cell and the second solar cell adjacent to the first solar cell. The first solar cell has the portion overlapping with the portion of the second solar cell. That is, any two adjacent solar cells among the plurality of solar cells partially overlap with each other.

That is, the plurality of solar cells are shingled solar cells. Compared with single-cell solar cells and conventional solar cells with standard spacing in the related art, consistency of appearance of the solar module can be ensured and aesthetics of the photovoltaic tile can be enhanced.

A portion of the first solar cell overlaps with and is electrically connected to a portion of the second solar cell. That is, any two adjacent solar cells among the plurality of solar cells are electrically connected to each other using shingling technology. This means that the solar module adopts a ribbon-free design, thereby effectively avoiding placement of welding ribbons on the light-receiving side of the solar module, which can otherwise block a light-receiving surface of the solar module. In this way, a power generation efficiency of the photovoltaic tile can be enhanced.

In addition, since the solar module is not provided with a welding ribbon, there is no stress concentration of the welding ribbon. During lamination, the solar cell is less prone to cracking, providing a larger process adaptation space.

Moreover, due to absence of welding ribbons, stress-induced pulling during curving and forming of the solar module can be avoided, which allows the solar module to be more easily curved, enabling the photovoltaic tile to achieve a greater curvature, thereby enhancing aesthetics of the photovoltaic tile.

Further, since the first solar cell and the second solar cell are electrically connected to each other without the welding ribbon, resulting in a simple manufacturing process, which is beneficial to reducing a manufacturing cost of the photovoltaic tile.

The at least one of the first plate body and the second plate body is configured as the rigid curved panel. In an exemplary embodiment of the present disclosure, the first plate body is the rigid curved panel. Or, the second plate body is the rigid curved panel. Or, the first plate body and the second plate body are both rigid curved panels. Specific settings can be made as desired.

The rigid curved panel includes the plurality of curved portions that are sequentially connected to each other, in such a manner that the photovoltaic tile has a high similarity to conventional roof tiles, thereby improving aesthetics of roof surfaces.

In addition, the photovoltaic tile according to the above technical solutions of the present disclosure can further have the following additional technical features.

In another exemplary embodiment of the present disclosure, any two adjacent curved portions among the plurality of curved portions have opposite curvature directions.

In this technical solution, it is defined that at least one of the first plate body and the second plate body is a rigid curved panel having a plurality of peaks and a plurality of troughs. Therefore, the photovoltaic tile can bear a higher resemblance to conventional roof tiles, thereby maintaining integrity and aesthetics of the roof surfaces.

In another exemplary embodiment of the present disclosure, the solar module further includes a conductive connector. The first solar cell is electrically connected to the second solar cell through the conductive connector.

In this technical solution, it is defined that the solar module further includes the conductive connector. In another exemplary embodiment of the present disclosure, any two adjacent solar cells among the plurality of solar cells are electrically connected to each other through the conductive connector to achieve series connection.

In some technical solutions, the conductive connector is disposed at an overlapping portion between the first solar cell and the second solar cell and located between the first solar cell and the second solar cell.

In this technical solution, the conductive connector is disposed at the overlapping portion between the first solar cell and the second solar cell, and the conductive connector is located between the first solar cell and the second solar cell. Compared with any adjacent solar cells connected to each other by a welding ribbon in the related art, the welding ribbon can effectively be prevented from blocking the light-receiving surface of the solar module, and thus the power generation efficiency of the photovoltaic tile can be improved. Moreover, during the lamination, stress concentration at a position where the welding ribbon is located is avoided, which leads to cracking of the solar cell and facilitates the curving and forming of the solar module.

In another exemplary embodiment of the present disclosure, each of the plurality of solar cells includes a positive electrode layer and a negative electrode layer. A negative electrode layer of the first solar cell is electrically connected to a positive electrode layer of the second solar cell through the conductive connector.

In this technical solution, it is defined that each solar cell includes the positive electrode layer and the negative electrode layer. In another exemplary embodiment of the present disclosure, the negative electrode layer of the first solar cell is electrically connected to the positive electrode layer of the second solar cell through the conductive connector, thereby realizing series connection between any adjacent solar cells.

In another exemplary embodiment of the present disclosure, each of the plurality of solar cells further includes a chip layer. In a thickness direction of the solar cell, the positive electrode layer and the negative electrode layer are located at two sides of the chip layer, respectively, the chip layer being capable of converting light energy into electrical energy.

In this technical solution, it is defined that each solar cell further includes the chip layer. In another exemplary embodiment of the present disclosure, the positive electrode layer and the negative electrode layer are located at two sides of the chip layer, respectively, in the thickness direction of the solar cell. Therefore, while any two adjacent solar cells partially overlap, electrical connection is realized through the conductive connector without welding ribbon, simplifying a preparation process and thus reducing the manufacturing cost of the photovoltaic tile.

In another exemplary embodiment of the present disclosure, the solar cell includes a shingled crystalline silicon solar cell.

In another exemplary embodiment of the present disclosure, the positive electrode layer is located at a light-receiving side of the chip layer, and the negative electrode layer is located at a rear side of the chip layer.

In another exemplary embodiment of the present disclosure, the overlapping portion between the first solar cell and the second solar cell is an overlapping region. The conductive connector is located within the overlapping region.

In this technical solution, the conductive connector is located within the overlapping region of any two adjacent solar cells. That is, in a direction of light incident on the photovoltaic tile, a projection of the conductive connector lies within a projection range of the overlapping region, meaning that the conductive connector does not extend beyond an outer edge of the overlapping region. Therefore, shading of the light-receiving surface of the solar cells caused by an excessive width of the conductive connector is avoided while achieving effective connection between any two adjacent solar cells, thereby improving a power generation capacity of the photovoltaic tile.

In another exemplary embodiment of the present disclosure, in a width direction of the solar cell, the conductive connector has a first end aligned with an end of the first solar cell located within the overlapping region; and/or in the width direction of the solar cell, the conductive connector has a second end aligned with an end of the second solar cell located within the overlapping region.

In the technical solution, in the width direction of the solar cell, the conductive connector has the first end aligned with the end of the first solar cell located within the overlapping region, ensuring effective connection between any two adjacent solar cells while ensuring that the conductive connector does not extend beyond an outer edge of the overlapping region to improve the power generation efficiency of the photovoltaic tile, thereby improving reliability of the photovoltaic tile, and thus prolonging a service life of the photovoltaic tile.

In the width direction of the solar cell, the conductive connector has the second end aligned with the end of the second solar cell located within the overlapping region, ensuring the effective connection between any two adjacent solar cells while ensuring that the conductive connector does not extend beyond the outer edge of the overlapping region to improve the power generation efficiency of the photovoltaic tile, thereby improving the reliability of the photovoltaic tile, and thus prolonging the service life of the photovoltaic tile.

In another exemplary embodiment of the present disclosure, the conductive connector includes a conductive adhesive.

In the technical solution, it is defined that the conductive connector includes the conductive adhesive, in such a manner that a preparation process of the photovoltaic tile can be simplified, and thus the manufacturing cost of the photovoltaic tile can be reduced.

In a specific embodiment, a negative electrode layer of a first shingled solar cell (the first solar cell) is lap jointed with a positive electrode layer of a second shingled solar cell (the second solar cell) by using conductive adhesive. When a solar cell group (a solar module) is subjected to a high temperature and a high pressure, the conductive adhesive melts, and a positive electrode and a negative electrode of the two shingled solar cells are lap jointed with each other. When the temperature returns to a room temperature, the positive electrode and the negative electrode of the two shingled solar cells are fixed together, thereby achieving series connection of the solar cells.

In another exemplary embodiment of the present disclosure, the conductive connector is disposed at a rear side of the first solar cell and a rear side of the second solar cell, and the conductive connector is adhered to at least one of the first solar cell and the second solar cell.

In the technical solution, it is defined that part of the first solar cell overlaps with part of the second solar cell. That is, adjacent solar cells are arranged in a shingled configuration.

The conductive connector is adhered to at least one of the first solar cell and the second solar cell. In particular, the conductive connector is adhered to the first solar cell. Or, the conductive connector is adhered to the second solar cell. Or, the conductive connector is adhered to both the first solar cell and the second solar cell. Specific settings can be made as desired.

Since the conductive connector is adhered to the first solar cell and/or the second solar cell, connection strength between the conductive connector and the first solar cell and/or the second solar cell can be improved, ensuring effective series connection between the first solar cell and the second solar cell, and thus improving the reliability and the service life of the photovoltaic tile.

It should be understood that when the conductive connector is adhered to both the first solar cell and the second solar cell, the first solar cell and the second solar cell can be effectively fixed to ensure that a lamination process or curving and forming can proceed smoothly, preventing the solar cells from cracking.

In another exemplary embodiment of the present disclosure, the conductive connector includes: a first connection portion adhered to a rear side surface of the first solar cell; and a second connection portion adhered to a rear side surface of the second solar cell.

In the technical solution, it is defined that the conductive connector includes the first connection portion and the second connection portion. In particular, the first connection portion is adhered to the rear side surface of the first solar cell, thereby improving connection strength between the first connection portion and the first solar cell. The second connection portion is adhered to the rear side surface of the second solar cell, thereby improving connection strength between the second connection portion and the second solar cell, realizing effective series connection between the first solar cell and the second solar cell, and thus ensuring the reliability of the photovoltaic tile.

In addition, the first solar cell and the second solar cell can be effectively fixed to ensure that the lamination process or curving and forming can proceed smoothly, preventing the solar cells from cracking, and thus improving a yield of the photovoltaic tile.

In another exemplary embodiment of the present disclosure, the conductive connector further includes a third connection portion located between the first connection portion and the second connection portion and connected to the first connection portion and the second connection portion. In a width direction of the solar cell, an end surface of an end of the second solar cell close to the first solar cell is adhered to the third connection portion.

In the technical solution, it is defined that the conductive connector further includes the third connection portion. In particular, the third connection portion is located between the first connection portion and the second connection portion. In particular, the third connection portion has an end connected to the first connection portion, and another end connected to the second connection portion.

In the width direction of the solar cell, the end surface of the end of the second solar cell close to the first solar cell is adhered to the third connection portion, thereby further improving a fixation effect of the overlapping portion between the first solar cell and the second solar cell, further ensuring stability of the solar module in the lamination process or the curving and forming process. In this way, the lamination process or the curving and forming can proceed smoothly, preventing the solar cell from cracking, and thus improving the yield of the photovoltaic tile.

In another exemplary embodiment of the present disclosure, the first connection portion, the second connection portion, and the third connection portion are integrally formed as a single-piece structure.

In another exemplary embodiment of the present disclosure, the solar module further includes a solar cell group including a plurality of solar cells.

In the technical solution, it is defined that the solar module further includes the solar cell group, and the solar cell group includes the plurality of solar cells. That is, a whole solar cell group is cut into a plurality of solar cells, i.e., the whole solar cell group is cut into smaller solar cells. In this way, during welding and lamination for curved photovoltaic products, the smaller solar cells exhibit less deformation and are less prone to breakage, which can ensure a higher processing yield for the photovoltaic tile, and enhanced reliability.

Moreover, by dividing the entire solar cell group into smaller solar cells, it is possible to adapt to the encapsulation of various curved photovoltaic products, allowing for flexible product dimensions and circuit designs.

In another exemplary embodiment of the present disclosure, the number of solar cells into which a solar cell group can be divided is greater than or equal to 3. In particular, the number can be 4, 8, or 16.

In another exemplary embodiment of the present disclosure, the plurality of solar cell groups are provided. Each solar cell group is cut into a plurality of solar cells.

In another exemplary embodiment of the present disclosure, each of the plurality of solar cells includes: a positive electrode layer, a negative electrode layer; and a chip layer capable of converting light energy into electrical energy, the positive electrode layer and the negative electrode layer both being located at a rear side of the chip layer. In any two adjacent solar cells that partially overlap, a positive electrode layer of one solar cell is electrically connected to a negative electrode layer of the other solar cell through the conductive connector.

In the technical solution, it is defined that each solar cell includes the chip layer, the positive electrode layer, and the negative electrode layer. In particular, the positive electrode layer and the negative electrode layer are located at the rear side of the chip layer. That is, each solar cell is a back-contact crystalline silicon solar cell or a stacked cell. That is, a positive electrode lead-out terminal and a negative electrode lead-out terminal of the chip layer are both on a back surface of the chip layer.

In another exemplary embodiment of the present disclosure, the solar cell includes an Interdigitated Back Contact solar cell (IBC).

In any two adjacent solar cells that partially overlap, the positive electrode layer of one solar cell is electrically connected to the negative electrode layer of the other solar cell through the conductive connector, thereby achieving series connection between any two adjacent solar cells that partially overlap.

In another exemplary embodiment of the present disclosure, the first plate body includes: a glass plate configured as a rigid curved glass; and a first adhesive film disposed between the glass plate and a light-receiving side of the solar module.

In the technical solution, it is defined that the first plate body includes the glass plate and the first adhesive film. In particular, the first adhesive film is disposed between the glass plate and a light-receiving side of the solar module. It should be understood that both the glass plate and the first adhesive film can transmit light.

The glass plate is the rigid curved glass, which makes photovoltaic tiles have a high similarity to conventional roof tiles, thereby improving aesthetics of the roof surfaces.

In another exemplary embodiment of the present disclosure, the second plate body includes: a back plate; and a second adhesive film disposed between a rear side of the solar module and the back plate.

In the technical solution, it is defined that the second plate body includes the back plate and the second adhesive film. In particular, the second adhesive film is disposed between the back plate and the rear side of the solar module. That is, in a thickness direction of the photovoltaic tile, the glass plate, the first adhesive film, the solar module, the second adhesive film, and the back plate are sequentially stacked and formed into a whole through lamination processing.

In another exemplary embodiment of the present disclosure, the back plate is configured as the rigid curved panel.

In another exemplary embodiment of the present disclosure, the back plate is a flexible component.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic structural view of a photovoltaic tile according to an embodiment of the present disclosure.

FIG. 2 is a schematic structural view of a solar module according to an embodiment of the present disclosure.

FIG. 3 is a schematic structural view of a photovoltaic tile according to another embodiment of the present disclosure.

FIG. 4 is a schematic structural view of a solar module according to another embodiment of the present disclosure.

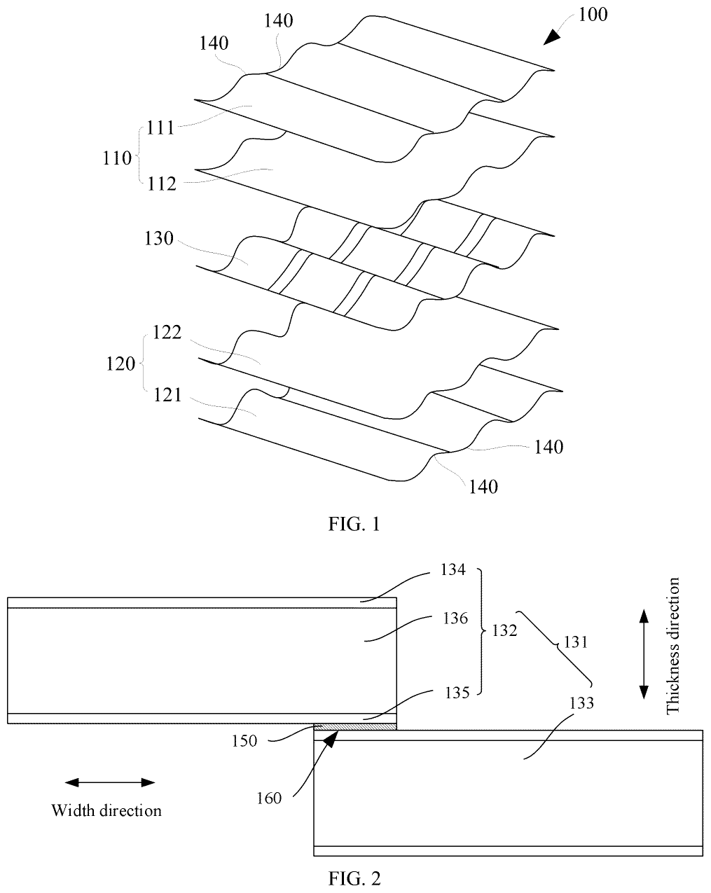

A correspondence between reference numerals and component names in FIG. 1 to FIG. 4 is as follows:

100 photovoltaic tile; 110 first plate body; 111 glass plate; 112 first adhesive film; 120 second plate body; 121 back plate; 122 second adhesive film; 130 solar module; 131 solar cell; 132 first solar cell; 133 second solar cell; 134 positive electrode layer; 135 negative electrode layer; 136 chip layer; 140 curved portion; 150 conductive connector; 160 overlapping region; 170 rear side; 180 light-receiving side.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limiting, the embodiments of the present disclosure.

Various embodiments or examples for implementing different structures of the embodiments of the present disclosure are provided below. In order to simplify the description of the embodiments of the present disclosure, components and arrangements of specific examples are described herein. Of course, these specific examples are merely for the purpose of illustration, rather than limiting the present disclosure. Further, the same reference numerals and/or reference letters may appear in different examples of the embodiments of the present disclosure for the purpose of simplicity and clarity, instead of indicating a relationship between different embodiments and/or the discussed arrangements. In addition, the embodiments of the present disclosure provide examples of various specific processes and materials. However, applications of other processes and/or the use of other materials are conceivable for those of ordinary skill in the art.

A photovoltaic tile 100 according to some embodiments of the present disclosure is described below with reference to FIG. 1 to FIG. 2.

In an embodiment according to the present disclosure, as illustrated in FIG. 1, a photovoltaic tile 100 is provided. The photovoltaic tile 100 includes: a first plate body 110 and a second plate body 120; a solar module 130 disposed between the first plate body 110 and the second plate body 120. The solar module 130 includes a plurality of solar cells 131. The plurality of solar cells 131 includes at least a first solar cell 132 and a second solar cell 133 adjacent to the first solar cell 132. The first solar cell 132 has a portion overlapping with and is electrically connected to a portion of the second solar cell 133. At least one of the first plate body 110 and the second plate body 120 is configured as a rigid curved panel. The rigid curved panel includes a plurality of curved portions 140 that are sequentially connected to each other.

The photovoltaic tile 100 according to the embodiment of the present disclosure includes the first plate body 110, the second plate body 120, and the solar module 130. In particular, the solar module 130 is disposed between the first plate body 110 and the second plate body 120. In another exemplary embodiment of the present disclosure, the first plate body 110 is located at a light-receiving side of the solar module 130. The second plate body 120 is located at a rear side of the solar module 130. The first plate body 110 can transmit light, in such a manner that the solar module 130 can convert light energy into electrical energy under illumination conditions.

The solar module 130 includes the plurality of solar cells 131. The plurality of solar cells 131 include at least the first solar cell 132 and the second solar cell 133 adjacent to the first solar cell 132. In addition, the first solar cell 132 has the portion overlapping with the portion of the second solar cell 133. That is, any two adjacent solar cells 131 among the plurality of solar cells 131 partially overlap.

That is, the plurality of solar cells 131 are shingled solar cells. Compared with single solar cell and conventional solar cells with a standard spacing in the related art, consistency of appearance of the solar module 130 can be ensured and aesthetics of the photovoltaic tile 100 can be enhanced.

The portion of the first solar cell 132 overlaps with and is electrically connected to the portion of the second solar cell 133. That is, any two adjacent solar cells 131 among the plurality of solar cells 131 are electrically connected to each other using shingling technology. This means that the solar module 130 adopts a ribbon-free design, thereby effectively avoiding welding ribbons being disposed at the light-receiving side of the solar module 130, which can otherwise block a light-receiving surface of the solar module 130. In this way, a power generation efficiency of the photovoltaic tile 100 can be enhanced.

In addition, since the solar module 130 is not provided with a welding ribbon, there is no stress concentration of the welding ribbon. During lamination, the solar cell 131 is less prone to cracking, providing a larger process adaptation space.

Moreover, due to absence of welding ribbons, stress-induced pulling during curving and forming of the solar module 130 can be avoided, which allows the solar module 130 to be more easily curved, enabling the photovoltaic tile 100 to achieve a greater curvature, thereby enhancing aesthetics of the photovoltaic tile 100.

Further, since the first solar cell 132 and the second solar cell 133 are electrically connected to each other without the welding ribbon, resulting in a simple manufacturing process, which is beneficial to reducing a manufacturing cost of the photovoltaic tile 100.

The at least one of the first plate body 110 and the second plate body 120 is configured as the rigid curved panel. In an exemplary embodiment of the present disclosure, the first plate body 110 is the rigid curved panel. Or, the second plate body 120 is the rigid curved panel. Or, both the first plate body 110 and the second plate body 120 are the rigid curved panels. Specific settings can be made as desired.

The rigid curved panel includes the plurality of curved portions 140 that are sequentially connected to each other, which makes photovoltaic tiles 100 have a high similarity to conventional roof tiles, thereby improving aesthetics of the roof surfaces.

As illustrated in FIG. 1, in another exemplary embodiment of the present disclosure, any two adjacent curved portions 140 among the plurality of curved portions 140 have opposite curvature directions.

In this embodiment, it is defined that at least one of the first plate body 110 and the second plate body 120 is a rigid curved panel having a plurality of peaks and a plurality of troughs. Therefore, the photovoltaic tile 100 can bear a higher resemblance to conventional roof tiles, thereby maintaining integrity and aesthetics of the roof surfaces.

As illustrated in FIG. 2, in another exemplary embodiment of the present disclosure, the solar module 130 further includes a conductive connector 150 disposed at an overlapping portion between the first solar cell 132 and the second solar cell 133 and located between the first solar cell 132 and the second solar cell 133. The first solar cell 132 is electrically connected to the second solar cell 133 through the conductive connector 150.

In this embodiment, it is defined that the solar module 130 further includes the conductive connector 150. In particular, the conductive connector 150 is disposed at the overlapping portion between the first solar cell 132 and the second solar cell 133 and located between the first solar cell 132 and the second solar cell 133. That is, any adjacent two solar cells 131 among the plurality of solar cells 131 are electrically connected to each other through the conductive connector 150 to achieve series connection.

Therefore, compared with any adjacent solar cells connected to each other by a welding ribbon in the related art, the welding ribbon can effectively be prevented from blocking the light-receiving surface of the solar module 130, and thus the power generation efficiency of the photovoltaic tile 100 can be improved. Moreover, during the lamination, stress concentration at a position where the welding ribbon is located and is prone to cracking of the solar cell 131 is avoided, which facilitates the curving and forming of the solar module 130.

As illustrated in FIG. 2, in another exemplary embodiment of the present disclosure, each of the plurality of solar cells 131 includes a positive electrode layer 134 and a negative electrode layer 135. A negative electrode layer 135 of the first solar cell 132 is electrically connected to a positive electrode layer 134 of the second solar cell 133 through the conductive connector 150.

In this embodiment, it is defined that each solar cell 131 includes the positive electrode layer 134 and the negative electrode layer 135. In particular, the negative electrode layer 135 of the first solar cell 132 is electrically connected to the positive electrode layer 134 of the second solar cell 133 through the conductive connector 150, thereby realizing series connection between any adjacent solar cells 131.

As illustrated in FIG. 2, in another exemplary embodiment of the present disclosure, each of the plurality of solar cells 131 further includes a chip layer 136. In a thickness direction of the solar cell 131, the positive electrode layer 134 and the negative electrode layer 135 are located at two sides of the chip layer 136, respectively. The chip layer 136 is capable of converting light energy into electrical energy.

In this embodiment, it is defined that each solar cell 131 further includes the chip layer 136. In particular, in the thickness direction of the solar cell 131, the positive electrode layer 134 and the negative electrode layer 135 are located at two sides of the chip layer 136, respectively. Therefore, while any two adjacent solar cells 131 are partially overlap, electrical connection is realized through the conductive connector 150 without the welding ribbon, simplifying a preparation process and thus reducing the manufacturing cost of the photovoltaic tile 100.

In another exemplary embodiment of the present disclosure, the solar cell 131 includes a shingled crystalline silicon solar cell.

In another exemplary embodiment of the present disclosure, the positive electrode layer 134 is located at a light-receiving side of the chip layer 136, and the negative electrode layer 135 is located at a rear side of the chip layer 136.

As illustrated in FIG. 2, in another exemplary embodiment of the present disclosure, the overlapping portion between the first solar cell 132 and the second solar cell 133 is an overlapping region 160. The conductive connector 150 is located within the overlapping region 160.

In this embodiment, the conductive connector 150 is located within the overlapping region 160 of any two adjacent solar cells 131. That is, in a direction of light incident on the photovoltaic tile 100, a projection of the conductive connector 150 lies within a projection range of the overlapping region 160, meaning that the conductive connector 150 does not extend beyond an outer edge of the overlapping region 160. Therefore, shading of the light-receiving surface of the solar cells 131 caused by an excessive width of the conductive connector 150 is avoided while achieving effective connection between any two adjacent solar cells 131, thereby improving a power generation capacity of the photovoltaic tile 100.

As illustrated in FIG. 2, in another exemplary embodiment of the present disclosure, in a width direction of the solar cell 131, the conductive connector 150 has a first end aligned with an end of the first solar cell 132 located within the overlapping region 160; and/or in the width direction of the solar cell 131, the conductive connector 150 has a second end aligned with an end of the second solar cell 133 located within the overlapping region 160.

In this embodiment, in the width direction of the solar cell 131, the conductive connector 150 has the first end aligned with the end of the first solar cell 132 located within the overlapping region 160, ensuring effective connection between any two adjacent solar cells 131 while ensuring that the conductive connector 150 does not extend beyond the outer edge of the overlapping region 160 to improve the power generation efficiency of the photovoltaic tile 100, thereby improving reliability of the photovoltaic tile 100, and thus prolonging a service life of the photovoltaic tile 100.

In the width direction of the solar cell 131, the conductive connector 150 has the second end aligned with the end of the second solar cell 133 located within the overlapping region 160, ensuring the effective connection between any two adjacent solar cells 131 while ensuring that the conductive connector 150 does not extend beyond the outer edge of the overlapping region 160 to improve the power generation efficiency of the photovoltaic tile 100, thereby improving the reliability of the photovoltaic tile 100, and thus prolonging the service life of the photovoltaic tile 100.

In another exemplary embodiment of the present disclosure, the conductive connector 150 includes a conductive adhesive.

In this embodiment, it is defined that the conductive connector 150 includes the conductive adhesive, in such a manner that a preparation process of the photovoltaic tile 100 can be simplified, and thus the manufacturing cost of the photovoltaic tile 100 can be reduced.

In a specific embodiment, a negative electrode layer 135 of a first shingled solar cell (the first solar cell 132) is lap jointed with a positive electrode layer 134 of a second shingled solar cell (the second solar cell 133) by the conductive adhesive. When a solar cell group (a solar module 130) is subjected to a high temperature and a high pressure, the conductive adhesive melts, and a positive electrode and a negative electrode of the two shingled solar cells are lap jointed with each other. When the temperature returns to a room temperature, the positive electrode and the negative electrode of the two shingled solar cells are fixed together, thereby achieving series connection of the solar cells 131.

As illustrated in FIG. 1, in another exemplary embodiment of the present disclosure, the first plate body 110 includes: a glass plate 111 configured as a rigid curved glass; and a first adhesive film 112 disposed between the glass plate 111 and a light-receiving side of the solar module 130.

In this embodiment, it is defined that the first plate body 110 includes the glass plate 111 and the first adhesive film 112. In particular, the first adhesive film 112 is disposed between the glass plate 111 and the light-receiving side of the solar module 130. It should be understood that both the glass plate 111 and the first adhesive film 112 can transmit light.

The glass plate 111 is the rigid curved glass, which makes photovoltaic tiles 100 have a high similarity to conventional roof tiles, thereby improving aesthetics of the roof surfaces.

As illustrated in FIG. 1, in another exemplary embodiment of the present disclosure, the second plate body 120 includes a back plate 121 and a second adhesive film 122 that is disposed between a rear side of the solar module 130 and the back plate 121.

In this embodiment, it is defined that the second plate body 120 includes the back plate 121 and the second adhesive film 122. In particular, the second adhesive film 122 is disposed between the back plate 121 and the rear side of the solar module 130. That is, in a thickness direction of the photovoltaic tile 100, the glass plate 111, the first adhesive film 112, the solar module 130, the second adhesive film 122, and the back plate 121 are sequentially stacked and formed into a whole through lamination processing.

In another exemplary embodiment of the present disclosure, the back plate 121 is configured as the rigid curved panel.

In another exemplary embodiment of the present disclosure, the back plate 121 is a flexible component.

Currently, in roof photovoltaic modules in the related art, a cell string is generally connected in series using front-side welding or welding on both a front side and a back side to achieve series connection between the plurality of solar cells. This means that the welding ribbon is present on the front side of the cell string, or on both the front side and the back side of the cell string. The welding ribbon on the front side can block part of a light-receiving surface of the cell string, leading to a reduced power generation efficiency of the roof photovoltaic module.

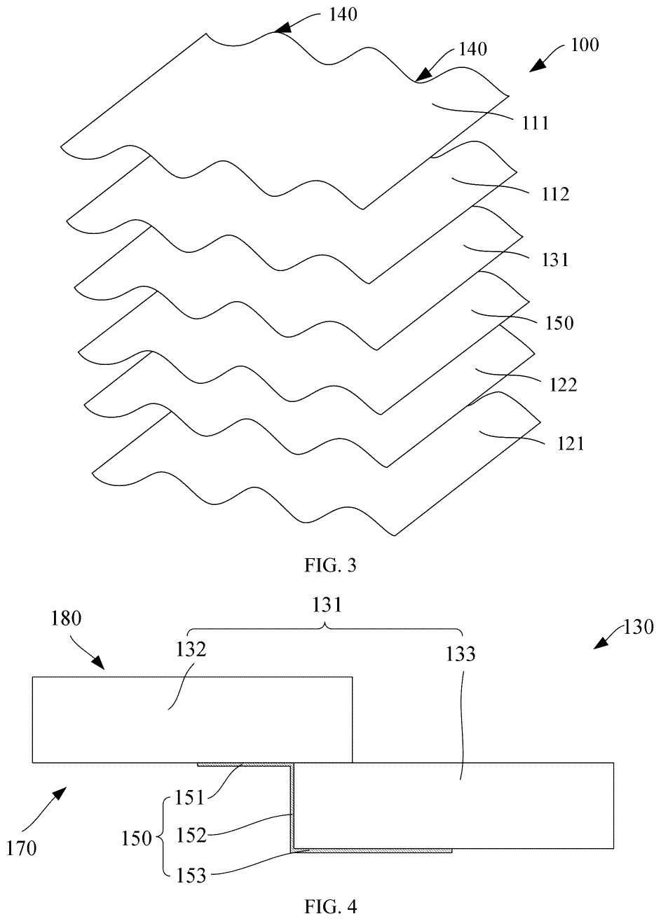

The solar module 130 and the photovoltaic tile 100 according to some embodiments of the present disclosure are described below with reference to FIG. 3 to FIG. 4.

In an embodiment according to the present disclosure, as illustrated in FIG. 3, the solar module 130 is provided. The solar module 130 includes: a plurality of solar cells 131, any two adjacent solar cells 131 among the plurality of solar cells 131 partially overlapping with each other, and each solar cell 131 being capable of converting the light energy into the electrical energy; and the conductive connector 150 disposed at rear sides 170 of the plurality of solar cells 131. At least two partially overlapping solar cells 131 are electrically connected to each other through the conductive connector 150.

The solar module 130 according to the embodiment of the present disclosure includes the plurality of solar cells 131 and the conductive connector 150. In particular, any two adjacent solar cells 131 among the plurality of solar cells 131 partially overlap with each other. In another exemplary embodiment of the present disclosure, the plurality of solar cells 131 include the first solar cell 132 and the second solar cell 133 adjacent to the first solar cell 132, and the first solar cell 132 has a portion overlapping with a portion of the second solar cell 133. That is, the plurality of solar cells 131 are shingled solar cells. Compared with single solar cell and conventional solar cells with a standard spacing in the related art, consistency of appearance of the solar module 130 can be ensured and aesthetics of the photovoltaic tile 100 can be enhanced.

The at least two partially overlapping solar cells 131 are electrically connected to each other through the conductive connector 150, thereby achieving series connection between at least two shingled solar cells 131.

In another exemplary embodiment of the present disclosure, among the plurality of solar cells 131 in the same row, any two adjacent solar cells 131 partially overlap, and the conductive connector 150 is connected to the plurality of solar cells 131. That is, any two adjacent solar cells 131 are electrically connected to each other through the conductive connector 150. In another exemplary embodiment of the present disclosure, the conductive connector 150 includes the welding ribbon.

In another exemplary embodiment of the present disclosure, the plurality of conductive connectors 150 are provided. Any two adjacent solar cells 131 are electrically connected to each other through one conductive connector 150. Specific settings can be made as desired.

Since each solar cell 131 can convert the light energy into the electrical energy, that is, under illumination conditions, light is incident on light-receiving sides 180 of the plurality of solar cells 131 and converted by the plurality of solar cells 131 to generate the electrical energy.

The conductive connector 150 is disposed at the rear sides 170 of the plurality of solar cells 131. That is, a welding ribbon located at the front surface of the cell string in the related art is eliminated. Therefore, the conductive connector 150 can effectively be prevented from blocking the light-receiving sides 180 of the plurality of solar cells 131 as compared with the welding ribbon located at the front surface of the cell string in the related art, enabling the solar module 130 to receive more solar irradiation. Therefore, the power generation efficiency and the power generation capacity of the photovoltaic tile 100 can be significantly improved.

Since the conductive connector 150 is disposed only at the rear sides 170 of the plurality of solar cells 131, when the solar module 130 undergoes lamination and curved forming, the conductive connector 150 located at the back side can effectively distribute a stress impact received by the overlapping portion of adjacent solar cells 131, thereby effectively reducing a cracking rate of the solar cell 131, and thus improving the yield of the photovoltaic tile 100.

In addition, by partially overlapping two adjacent solar cells 131 and then connecting the two adjacent solar cells 131 in series through the conductive connector 150, when the solar module 130 is laminated and curved, an edge position of the solar cell 131 can be stressed evenly, thereby reducing a breakage rate of the edge position of the solar cell 131.

Further, disposing the conductive connector 150 at the back sides of the plurality of solar cells 131 is also beneficial to improving the aesthetics of the photovoltaic tile 100.

As illustrated in FIG. 3, in another exemplary embodiment of the present disclosure, the plurality of solar cells 131 include the first solar cell 132 and the second solar cell 133 adjacent to the first solar cell 132. The first solar cell 132 has the portion overlapping with the portion of the second solar cell 133. The conductive connector 150 is adhered to at least one of the first solar cell 132 and the second solar cell 133.

In this embodiment, it is defined that the plurality of solar cells 131 include the first solar cell 132 and the second solar cell 133 adjacent to the first solar cell 132. In particular, a portion of the first solar cell 132 overlaps with a portion of the second solar cell 133. That is, adjacent solar cells 131 are arranged in a shingled configuration.

The conductive connector 150 is adhered to at least one of the first solar cell 132 and the second solar cell 133. In particular, the conductive connector 150 is adhered to the first solar cell 132. Or, the conductive connector 150 is adhered to the second solar cell 133. Or, the conductive connector 150 is adhered to both the first solar cell 132 and the second solar cell 133. Specific settings can be made as desired.

Since the conductive connector 150 is adhered to the first solar cell 132 and/or the second solar cell 133, connection strength between the conductive connector 150 and the first solar cell 132 and/or the second solar cell 133 can be improved, ensuring effective series connection between the first solar cell 132 and the second solar cell 133, and thus improving reliability and service life of the photovoltaic tile 100.

It should be understood that when the conductive connector 150 is adhered to both the first solar cell 132 and the second solar cell 133, the first solar cell 132 and the second solar cell 133 can be effectively fixed to ensure that a lamination process or curving and forming can proceed smoothly, preventing the solar cells 131 from cracking.

As illustrated in FIG. 3, in another exemplary embodiment of the present disclosure, the conductive connector 150 includes: a first connection portion 151 adhered to a rear side surface of the first solar cell 132; and a second connection portion 152 adhered to a rear side surface of the second solar cell 133.

In this embodiment, it is defined that the conductive connector 150 includes the first connection portion 151 and the second connection portion 152. In particular, the first connection portion 151 is adhered to the rear side surface of the first solar cell 132, thereby improving connection strength between the first connection portion 151 and the first solar cell 132. The second connection portion 152 is adhered to the rear side surface of the second solar cell 133, thereby improving connection strength between the second connection portion 152 and the second solar cell 133, realizing effective series connection between the first solar cell 132 and the second solar cell 133, and thus ensuring the reliability of the photovoltaic tile 100.

In addition, the first solar cell 132 and the second solar cell 133 can be effectively fixed to ensure that the lamination process or curving and forming can proceed smoothly, preventing the solar cells 131 from cracking, and thus improving a yield of the photovoltaic tile 100.

As illustrated in FIG. 3, in another exemplary embodiment of the present disclosure, the conductive connector 150 further includes a third connection portion 153 located between the first connection portion 151 and the second connection portion 152 and connected to the first connection portion 151 and the second connection portion 152. In a width direction of the solar cell 131, an end surface of an end of the second solar cell 133 close to the first solar cell 132 is adhered to the third connection portion 153.

In this embodiment, it is defined that the conductive connector 150 further includes the third connection portion 153. In particular, the third connection portion 153 is located between the first connection portion 151 and the second connection portion 152. In particular, the third connection portion 153 has an end connected to the first connection portion 151, and another end connected to the second connection portion 152.

In the width direction of the solar cell 131, the end surface of the end of the second solar cell 133 close to the first solar cell 132 is adhered to the third connection portion 153, thereby further improving a fixation effect of the overlapping portion between the first solar cell 132 and the second solar cell 133, further ensuring stability of the solar module 130 in the lamination process or the curving and forming process. In this way, the lamination process or the curving and forming can proceed smoothly, preventing the solar cell 131 from cracking, and thus improving the yield of the photovoltaic tile 100.

In another exemplary embodiment of the present disclosure, the first connection portion 151, the second connection portion 152, and the third connection portion 153 are integrally formed as a single-piece structure.

In another exemplary embodiment of the present disclosure, the solar module 130 further includes a solar cell group. The solar cell group includes a plurality of solar cells 131.

In this embodiment, the solar module 130 further includes the solar cell group. The solar cell group includes the plurality of solar cells 131. That is, a whole solar cell group is cut into a plurality of solar cells 131, i.e., the whole solar cell group is cut into smaller solar cells 131. In this way, during welding and lamination for curved photovoltaic products, the smaller solar cells exhibit less deformation and are less prone to breakage, which can ensure a higher processing yield for the photovoltaic tile 100, and enhanced reliability.

Moreover, by dividing the entire solar cell group into smaller solar cells 131, it is possible to adapt to encapsulation of various curved photovoltaic products, allowing for flexible product dimensions and circuit designs.

In another exemplary embodiment of the present disclosure, a number of solar cells into which a solar cell group can be divided is greater than or equal to 3. In particular, the number can be 4, 8, or 16.

In another exemplary embodiment of the present disclosure, the plurality of solar cell groups are provided. Each solar cell group is cut into the plurality of solar cells 131.

In another exemplary embodiment of the present disclosure, each of the plurality of solar cells 131 includes: a positive electrode layer, a negative electrode layer; and a chip layer capable of converting light energy into electrical energy. The positive electrode layer and the negative electrode layer are both located at a rear side 170 of the chip layer. In any two adjacent solar cells 131 that partially overlap, a positive electrode layer of one solar cell 131 is electrically connected to a negative electrode layer of the other solar cell 131 through the conductive connector 150.

In this embodiment, it is defined that each solar cell 131 includes the chip layer, the positive electrode layer, and the negative electrode layer. In particular, the positive electrode layer and the negative electrode layer are located at the rear side 170 of the chip layer. That is, each solar cell 131 is a back-contact crystalline silicon solar cell or a stacked cell. That is, a positive electrode lead-out terminal and a negative electrode lead-out terminal of the chip layer are both on a back surface of the chip layer.

In another exemplary embodiment of the present disclosure, the solar cell 131 includes an Interdigitated Back Contact solar cell (IBC).

In any two adjacent solar cells 131 that partially overlap, the positive electrode layer of one solar cell 131 is electrically connected to the negative electrode layer of the other solar cell 131 through the conductive connector 150, thereby achieving series connection between any two adjacent solar cells 131 that partially overlap.

According to a second aspect of the present disclosure, the photovoltaic tile 100 is provided. The photovoltaic tile 100 includes the solar module 130 according to any of the above-described embodiments, and thus has all the advantageous technical effects of the solar module 130, and thus details thereof will be omitted here.

As illustrated in FIG. 4, in another exemplary embodiment of the present disclosure, the photovoltaic tile 100 further includes the glass plate 111, the first adhesive film 112, the back plate 121, and the second adhesive film 122. The first adhesive film 112 is disposed between the glass plate 111 and the light-receiving side 180 of the solar module 130. The second adhesive film 122 is disposed between the back plate 121 and the rear side 170 of the solar module 130.

In this embodiment, it is defined that the photovoltaic tile 100 includes the solar module 130, the glass plate 111, the first adhesive film 112, the back plate 121, and the second adhesive film 122. In particular, the first adhesive film 112 is disposed between the glass plate 111 and the light-receiving sides 180 of the solar module 130. It should be understood that both the glass plate 111 and the first adhesive film 112 can transmit light.

The second adhesive film 122 is disposed between the back plate 121 and the rear side 170 of the solar module 130. That is, in the thickness direction of the photovoltaic tile 100, the glass plate 111, the first adhesive film 112, the solar module 130, the second adhesive film 122, and the back plate 121 are sequentially stacked and formed into a whole through lamination processing.

As illustrated in FIG. 4, in another exemplary embodiment of the present disclosure, the at least one of the glass plate 111 and the back plate 121 is configured as the rigid curved panel.

In this embodiment, in particular, the glass plate 111 is the rigid curved panel. Alternatively, the back plate 121 is the rigid curved panel. Alternatively, both the glass plate 111 and the back plate 121 are rigid curved panels. Specific settings can be made as desired.

The glass plate 111, the first adhesive film 112, the solar module 130, the second adhesive film 122, and the back plate 121 are sequentially stacked and formed into a whole through lamination processing, i.e., the photovoltaic tile 100. Since the at least one of the glass plate 111 and the back plate 121 is the rigid curved panel, the formed photovoltaic tile 100 is a curved photovoltaic tile. It should be understood that curved photovoltaic tiles have a higher similarity to conventional roof surfaces, ensuring the integrity and the aesthetics of the roof surfaces.

As illustrated in FIG. 4, in another exemplary embodiment of the present disclosure, the rigid curved panel includes the plurality of curved portions 140 that are sequentially connected to each other.

In this embodiment, the rigid curved panel includes the plurality of curved portions 140 that are sequentially connected to each other, which makes photovoltaic tiles 100 have a higher similarity to conventional roof tiles, thereby improving the aesthetics of the roof surfaces.

In another exemplary embodiment of the present disclosure, any two adjacent curved portions 140 among the plurality of curved portions 140 have opposite curvature directions. That is, at least one of the glass plate 111 and the back plate 121 is a rigid curved panel having a plurality of peaks and a plurality of troughs. Therefore, the photovoltaic tile 100 can bear a higher resemblance to conventional roof tiles, thereby maintaining integrity and aesthetics of the roof surfaces.

In a specific embodiment, as illustrated in FIG. 3, a first XBC solar cell (the first solar cell 132) and a second XBC solar cell (the second solar cell 133) are welded to and connected in series with each other through a back-side welding ribbon (the conductive connector 150). When a plurality of sets of XBC solar cells are lap jointed to each other through welding, the XBC cell circuit can be connected in series.

In the present disclosure, the description with reference to the terms “one embodiment,” “some embodiments,” “an illustrative embodiment,” “an example,” “a specific example,” or “some examples,” etc., means that specific features, structures, materials, or characteristics described in conjunction with the embodiment(s) or example(s) are included in at least one embodiment or example of the present disclosure. In the present disclosure, any illustrative reference of the above terms does not necessarily refer to the same embodiment(s) or example(s). Moreover, the specific features, structures, materials, or characteristics as described can be combined in any one or more embodiments or examples as appropriate.

Although embodiments of the present disclosure have been illustrated and described, it is conceivable for those skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A photovoltaic tile, comprising:
a first plate body and a second plate body; and
a solar module disposed between the first plate body and the second plate body, the solar module comprising a plurality of solar cells, the plurality of solar cells comprising at least a first solar cell and a second solar cell adjacent to the first solar cell, and the first solar cell having a portion overlapping with and being electrically connected to a portion of the second solar cell,
wherein at least one of the first plate body and the second plate body is configured as a rigid curved panel, the rigid curved panel comprising a plurality of curved portions that are sequentially connected to each other.

2. The photovoltaic tile according to claim 1, wherein any two adjacent curved portions among the plurality of curved portions have opposite curvature directions.

3. The photovoltaic tile according to claim 1, wherein the solar module further comprises:
a conductive connector, the first solar cell being electrically connected to the second solar cell through the conductive connector.

4. The photovoltaic tile according to claim 3, wherein the conductive connector is disposed at an overlapping portion between the first solar cell and the second solar cell and located between the first solar cell and the second solar cell.

5. The photovoltaic tile according to claim 4, wherein:
each of the plurality of solar cells comprises a positive electrode layer and a negative electrode layer; and
a negative electrode layer of the first solar cell is electrically connected to a positive electrode layer of the second solar cell through the conductive connector.

6. The photovoltaic tile according to claim 5, wherein each of the plurality of solar cells further comprises:
a chip layer, wherein in a thickness direction of the solar cell, the positive electrode layer and the negative electrode layer are located at two sides of the chip layer, respectively, the chip layer being capable of converting light energy into electrical energy.

7. The photovoltaic tile according to claim 4, wherein:
the overlapping portion between the first solar cell and the second solar cell is an overlapping region; and
a projection of the conductive connector is located within a projection range of the overlapping region.

8. The photovoltaic tile according to claim 7, wherein:
in a width direction of the solar cell, the conductive connector has a first end aligned with an end of the first solar cell located within the overlapping region; and/or
in the width direction of the solar cell, the conductive connector has a second end aligned with an end of the second solar cell located within the overlapping region.

9. The photovoltaic tile according to claim 4, wherein the conductive connector comprises a conductive adhesive.

10. The photovoltaic tile according to claim 3, wherein the conductive connector is disposed at a rear side of the first solar cell and a rear side of the second solar cell, and the conductive connector is adhered to at least one of the first solar cell and the second solar cell.

11. The photovoltaic tile according to claim 10, wherein the conductive connector comprises:
a first connection portion adhered to a rear side surface of the first solar cell; and
a second connection portion adhered to a rear side surface of the second solar cell.

12. The photovoltaic tile according to claim 11, wherein the conductive connector further comprises a third connection portion located between the first connection portion and the second connection portion and connected to the first connection portion and the second connection portion,
wherein in a width direction of the solar cell, an end face of an end of the second solar cell close to the first solar cell is adhered to the third connection portion.

13. The photovoltaic tile according to claim 10, wherein the solar module further comprises a solar cell group comprising a plurality of solar cells.

14. The photovoltaic tile according to claim 10, wherein each of the plurality of solar cells comprises:
a positive electrode layer and a negative electrode layer, a negative electrode layer of the first solar cell being electrically connected to a positive electrode layer of the second solar cell through the conductive connector; and
a chip layer, the positive electrode layer and the negative electrode layer both being located at a rear side of the chip layer, and the chip layer being capable of converting light energy into electrical energy.

15. The photovoltaic tile according to claim 1, wherein the first plate body comprises:
a glass plate configured as a rigid curved glass; and
a first adhesive film disposed between the glass plate and a light-receiving side of the solar module.

16. The photovoltaic tile according to claim 1, wherein the second plate body comprises:
a back plate; and
a second adhesive film disposed between a rear side of the solar module and the back plate.

17. The photovoltaic tile according to claim 1, wherein the solar cell comprises a shingled crystalline silicon solar cell.

18. The photovoltaic tile according to claim 12, wherein the first connection portion, the second connection portion, and the third connection portion are integrally formed as a single-piece structure.

19. The photovoltaic tile according to claim 14, wherein the solar cell comprises an interdigitated back contact solar cell.

20. The photovoltaic tile according to claim 16, wherein the back plate is configured as the rigid curved panel or the back plate is a flexible component.
